(19) United States
(12) Patent Application Publication
(10) Pub. No.: US 2010/0301356 A1
(43) Pub. Date: Dec. 2, 2010

(54) LIGHT SOURCE HAVING LIGHT EMITTING CELLS ARRANGED TO PRODUCE A SPHERICAL EMISSION PATTERN

(75) Inventors: Keith SCOTT, Sunnyvale, CA (US); Jason Posselt, Sunnyvale, CA (US); Rene Helbing, Sunnyvale, CA (US)

Correspondence Address: Arent Fox LLP, 555 West Fifth Street, 48th Floor, Los Angeles, CA, 90013, US

(73) Assignee: Bridgelux, Inc., Sunnyvale, CA (US)

(21) Appl. No.: 12/645,284

(22) Filed: Dec. 22, 2009

Related U.S. Application Data
(60) Provisional application No. 61/183,402, filed on Jun. 2, 2009.

(51) Int. Cl. H01L 33/00

(52) U.S. Cl. 257/91; 257/98; 257/99; 257/E33.056; 257/E33.075; 257/E33.067

(57) ABSTRACT

A light source includes a mount having first and second opposite surfaces, a first light emitting element having one or more solid state light emitting cells arranged to emit light from the first surface of the mount, and a second light emitting element having one or more solid state light emitting cells arranged to emit light from the second surface of the mount. The first and second light emitting elements are arranged such that the light emitted from the light source produces a substantially spherical emission pattern.

### CROSS-REFERENCE TO RELATED APPLICATION

Pursuant to 35 U.S.C. §119(e), this application claims the benefit of U.S. Provisional

Application Ser. No. 61/183,402 filed on Jun. 2, 2009, the contents of which is hereby incorporated by reference in its entirety.

### BACKGROUND

1. Field

The present disclosure relates to light sources, and more particularly to light sources having light emitting cells arranged to produce a spherical emission pattern.

2. Background

Solid state devices, such as light emitting diodes (LED)s, are attractive candidates for replacing conventional light sources such as incandescent, halogen and fluorescent lamps. LEDs have substantially higher light conversion efficiencies than incandescent and halogen lamps and longer lifetimes than all three of these types of conventional light sources. In addition, some types of LEDs now have higher conversion efficiencies than fluorescent light sources and still higher conversion efficiencies have been demonstrated in the laboratory.

The typical LED has a lambertian emission pattern. This means that light emitted from the LED typically spans a hemispherical arc. This emission pattern may limit the use of LED light sources, or other solid state lighting devices, as replacements for conventional light sources for incandescent, halogen and fluorescent lamps, which emit light in all directions. An LED light source that is used in an incandescent light bulb, for example, may result in undesired dark spots in the downward direction. In common lighting applications, such as desk, floor, or table lamps, this can result in no downward light to enable work or reading tasks.

Accordingly, there is a need in the art for a solid state light source that has an emission pattern that better resembles conventional incandescent, halogen and fluorescent lamps.

### SUMMARY

In one aspect of the disclosure, a light source includes a mount having first and second opposite surfaces, a first light emitting element having one or more solid state light emitting cells arranged to emit light from the first surface of the mount, and a second light emitting element having one or more solid state light emitting cells arranged to emit light from the second surface of the mount. The first and second light emitting elements are arranged such that the light emitted from the light source produces a substantially spherical emission pattern.

In another aspect of the disclosure, a light source includes a mount, a first light emitting element having one or more solid state light emitting cells, and a second light emitting element having one or more solid state light emitting cells. The first and second light emitting elements arranged with the mount to emit light in opposite directions so that the light emitted from the light source has a substantially spherical emission pattern.

In yet another aspect of the disclosure, a light source includes a mount, a first light emitting element having one or more solid state light emitting cells, and a second light emitting element having one or more solid state light emitting cells. The first and second light emitting elements are attached to opposite sides of the mount to produce a substantially spherical emission pattern from the light source.

In a further aspect of the disclosure, a lamp includes a housing having a base and a transparent bulb portion mounted to the base, and a light source within the housing. The light source includes a mount having first and second opposite surfaces, a first light emitting element having one or more solid state light emitting cells arranged to emit light from the first surface of the mount, and a second light emitting element having one or more solid state light emitting cells arranged to emit light from the second surface of the mount. The first and second light emitting elements are arranged such that the light emitted from the transparent bulb portion produces a substantially spherical emission pattern.

It is understood that other aspects of the present invention will become readily apparent to those skilled in the art from the following detailed description, wherein it is shown and described only exemplary configurations of a light source by way of illustration. As will be realized, the present invention includes other and different aspects of a light source and its several details are capable of modification in various other respects, all without departing from the spirit and scope of the present invention. Accordingly, the drawings and the detailed description are to be regarded as illustrative in nature and not as restrictive.

### BRIEF DESCRIPTION OF THE FIGURES

Various aspects of the present invention are illustrated by way of example, and not by way of limitation, in the accompanying drawings, wherein:

FIG. 1 is a conceptual cross-sectional side view illustrating an example of an LED;

FIG. 2 is a conceptual top view illustrating an example of a light emitting element;

FIG. 3A is a conceptual top view illustrating an example of a white light emitting element;

FIG. 3B is a conceptual cross-sectional side view of the white light emitting element of FIG. 3A;

FIG. 4 is a conceptual cross-sectional side view illustrating an example of a light source having a substantially spherical emission pattern; and

FIG. 5 is a conceptual cross-sectional side view of a lamp.

### DETAILED DESCRIPTION

The present invention is described more fully hereinafter with reference to the accompanying drawings, in which various aspects of the present invention are shown. This invention, however, may be embodied in many different forms and should not be construed as limited to the various aspects of the present invention presented throughout this disclosure. Rather, these aspects are provided so that this disclosure will be thorough and complete, and will fully convey the scope of the present invention to those skilled in the art. The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus or method.

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items

Various aspects of a light source will now be presented. However, as those skilled in the art will readily appreciate, these aspects may be extended to other light sources without departing from the spirit and scope of the invention. The light source may include a mount, a first light emitting element having one or more solid state light emitting cells arranged in a planar fashion, and a second light emitting element having one or more solid state light emitting cells arranged in a planar fashion. The planar configuration of the light emitting elements tends to simplify manufacturing and keep costs low. The first and second light emitting elements are mounted in opposing directions on the mount. Each light emitting element has a lambertian emission pattern, which when combined on the mount as described above, produce a substantially spherical emission patter. The light source may be used as a direct replacement for conventional light sources currently being used in incandescent, fluorescent, halogen, quartz, high-intensity discharge (HID), and neon lamps, to name a few.

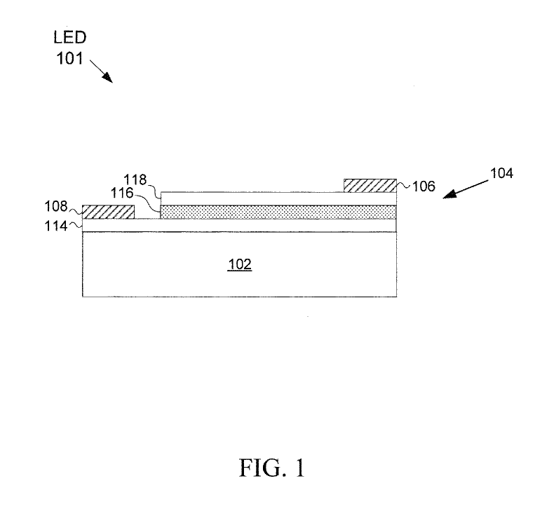

An example of a solid state light emitting cell is an LED. The LED is well known in the art, and therefore, will only briefly be discussed to provide a complete description of the invention. FIG. 1 is a conceptual cross-sectional side view illustrating an example of an LED. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, which are referred to as n-type or a p-type semiconductor region, respectively. In LED applications, the semiconductor includes an n-type semiconductor region and a p-type semiconductor region. A reverse electric field is created at the junction between the two regions, which cause the electrons and holes to move away from the junction to form an active region. When a forward voltage sufficient to overcome the reverse electric field is applied across the p-n junction, electrons and holes are forced into the active region and combine. When electrons combine with holes, they fall to lower energy levels and release energy in the form of light.

Referring to FIG. 1, the LED 101 includes a substrate 102, an epitaxial-layer structure 104 on the substrate 102, and a pair of electrodes 106 and 108 on the epitaxial-layer structure 104. The epitaxial-layer structure 104 comprises an active region 116 sandwiched between two oppositely doped epitaxial regions. In this example, an n-type semiconductor region 114 is formed on the substrate 102 and a p-type semiconductor region 118 is formed on the active region 116, however, the regions may be reversed. That is, the p-type semiconductor region 118 may be formed on the substrate 102 and the n-type semiconductor region 114 may formed on the active region 116. As those skilled in the art will readily appreciate, the various concepts described throughout this disclosure may be extended to any suitable epitaxial-layer structure. Additional layers (not shown) may also be included in the epitaxial-layer structure 104, including but not limited to buffer, nucleation, contact and current spreading layers as well as light extraction layers.

The electrodes 106 and 108 may be formed on the surface of the epitaxial-layer structure 104. The p-type semiconductor region 118 is exposed at the top surface, and therefore, the p-type electrode 106 may be readily formed thereon. However, the n-type semiconductor region 114 is buried beneath the p-type semiconductor region 118 and the active region 116. Accordingly, to form the n-type electrode 108 on the n-type semiconductor region 114, a portion of the active region 116 and the p-type semiconductor region 118 is removed to expose the n-type semiconductor region 114 therebeneath. After this portion of the epitaxial-layer structure 104 is removed, the n-type electrode 108 may be formed.

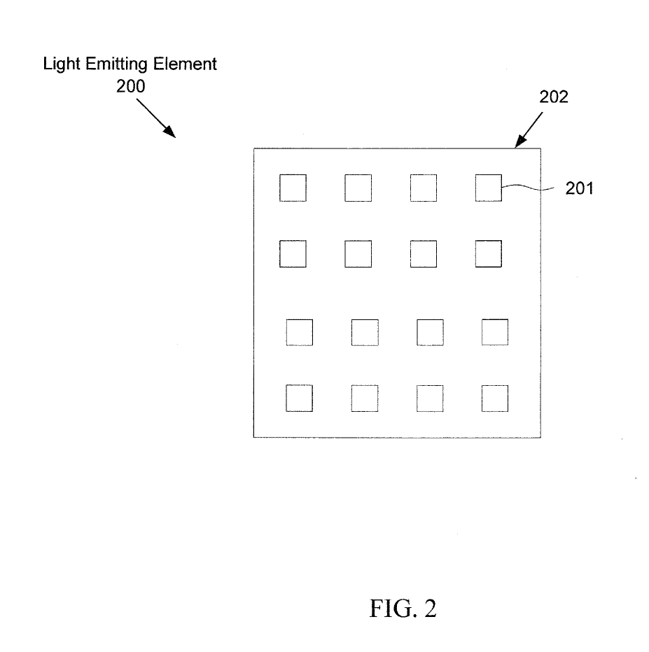

As discussed above, one or more light emitting cells may be used to construct a light emitting element. A light emitting element may be constructed in a 2-dimensional planar fashion. One example of a light emitting element will now be presented with reference to FIG. 2. FIG. 2 is a conceptual top view illustrating an example of a light emitting element. In this example, a light emitting element 200 is configured with multiple LEDs 201 arranged on a substrate 202. The substrate 202 may be made from any suitable material that provides mechanical support to the LEDs 201. Preferably, the material is thermally conductive to dissipate heat away from the LEDs 201. The substrate 202 may include a dielectric layer (not shown) to provide electrical insulation between the LEDs 201. The LEDs 201 may be electrically coupled in parallel and/or series by a conductive circuit layer, wire bonding, or a combination of these or other methods on the dielectric layer.

The light emitting element may be configured to produce white light. White light may enable the light emitting element to act as a direct replacement for conventional light sources used today in incandescent, halogen and fluorescent lamps. There are at least two common ways of producing white light. One way is to use individual LEDs that emit wavelengths (such as red, green, blue, amber, or other colors) and then mix all the colors to produce white light. The other way is to use a phosphor material or materials to convert monochromatic light emitted from a blue or ultra-violet (UV) LED to broad-spectrum white light. The present invention, however, may be practiced with other LED and phosphor combinations to produce different color lights.

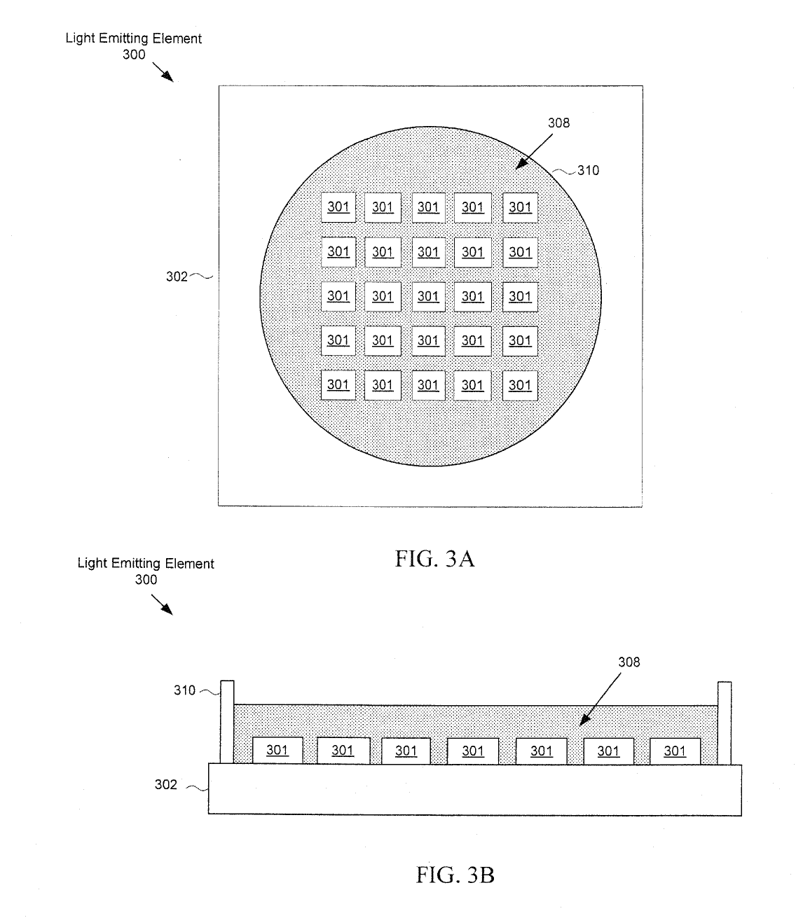

An example of a white light emitting element will now be presented with reference to FIGS. 3A and 3B. FIG. 3A is a conceptual top view illustrating an example of a white light emitting element and FIG. 3B is a conceptual cross-sectional side view of the white light emitting element in FIG. 3A. The white light emitting element 300 is shown with a substrate 302 which may be used to support multiple LEDs 301. The substrate 302 may be configured in a manner similar to that described in connection with FIG. 2 or in some other suitable way. A phosphor material 308 may be deposited within a cavity defined by an annular, or other shaped, or other boundary 310 that extends circumferentially, or in any shape, around the upper surface of the substrate 302. The annular boundary 310 may be formed with a suitable mold, or alternatively, formed separately from the substrate 302 and attached to the substrate 302 using an adhesive or other suitable means. The phosphor material 308 may include, by way of example, phosphor particles suspended in an epoxy, silicone, or other carrier or may be constructed from a soluble phosphor that is dissolved in the carrier.

In an alternative configuration of a white light emitting element, each LED may have its own phosphor layer. As those skilled in the art will readily appreciate, various configurations of LEDs and other light emitting cells may be used to create a white light emitting element. Moreover, as noted earlier, the present invention is not limited to solid state lighting devices that produce white light, but may be extended to solid state lighting devices that produce other colors of light.

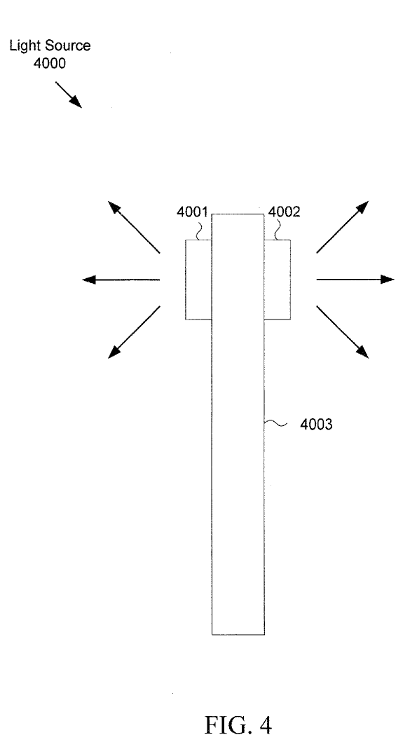

Two light emitting elements may be mounted in opposing directions to a mount to produce a substantially spherical emission pattern. An example will now be presented with reference to FIG. 4. FIG. 4 is a conceptual cross-sectional side view illustrating an example of a light source having a substantially spherical emission pattern. In this example, a light source 4000 includes a first light emitting element 4001 mounted to one side of a mount 4003 and a second lighting element 4002 mounted to the other side of the mount 4003. The light emitting elements 4001, 4002 may be mounted to the mount 4003 using an adhesive, or by some other suitable means. Preferably, the mount 4003 is thermally conductive to dissipate heat away from the light emitting elements. By way of example, the mount 4003 may be made of aluminum. The mount 4003 may be rectangular as shown, or some other suitable shape. A light emitting element may be constructed with one or more LEDs on a substrate, or multiple substrates with each substrate having one or more LEDs. Alternatively, a light emitting element may include one or more LEDs configured to be directly mounted to the mount, either in addition to or instead the one or more substrates with one or more LEDs each.

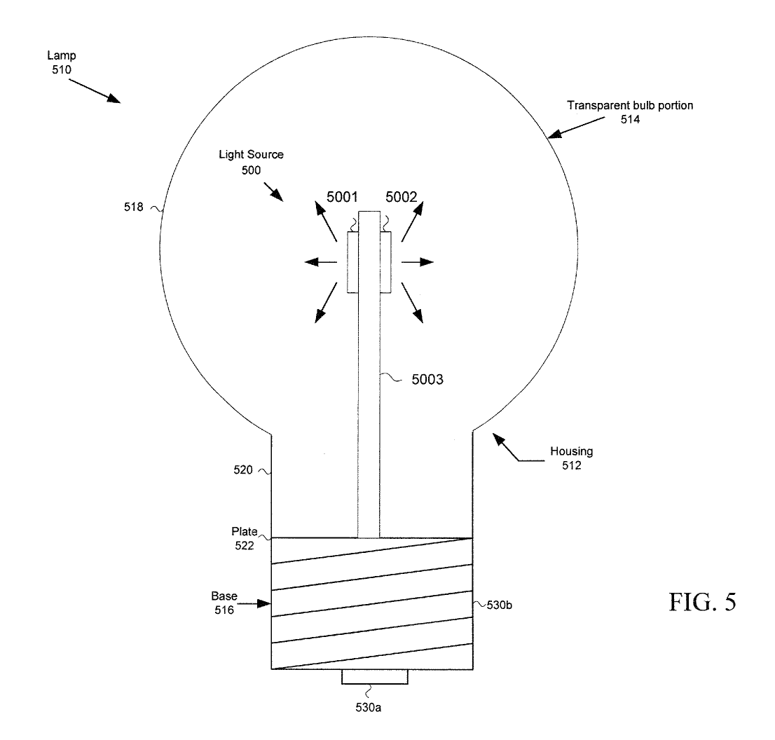

As noted earlier, a light source that produces a substantially spherical emission pattern from light emitting devices is well suited to function as a replacement light source in conventional incandescent, halogen and fluorescent lamps. An example will now be presented with reference to FIG. 5. FIG. 5 is a conceptual side view illustrating an example of a lamp with a light source having a pair of light emitting elements. The lamp 510 may include a housing 512 having a transparent bulb portion 514 (e.g., glass, plastic, etc.) mounted onto a base 516. The transparent bulb portion 514 may be have an internal diffusion coating to better diffuse the light emitted from the lamp 510. The internal surface of the transparent bulb portion 514 may also be coated with additional material that facilitates heat dissipation. Alternatively, the transparent bulb portion 514 may be filled with a fluid or gas that similarly provides diffusion and/or heat dissipation. The transparent bulb portion 514 is shown with a substantially circular or elliptical portion 518 extending from a neck portion 520, although the transparent bulb portion 514 may take on other shapes and forms depending on the particular application.

A light source 5000 may be positioned within the housing 512. The light source 5000 may include light emitting elements 5001, 5002 mounted in opposing directions on a mount 5003.

A plate 522 anchored to the base 516 provides support for the mount 5003. The plate 522 may be constructed from any suitable insulting material, including by way of example, glass. In the case of glass, the transparent bulb portion 514 of the housing 512 can be fused to the plate 522 to seal the light source 5000. The plate 522 also provides a feed through for routing wires (not shown) from the light source 5000 to electrical contacts 530a and 530b on the base 516.

The arrangement of electrical contacts 530a and 530b and physical shape of the connecting lamp base may vary depending on the particular application. By way of example, the lamp 510 may have a base 516 with a screw cap configuration, as shown in FIG. 5, with one electrical contact 530a at the tip of the base 516 and the screw cap serving as the other electrical contact 530b. Contacts in the lamp socket (not shown) allow electrical current to pass through the base 516 to the light source 5000. Alternatively, the base may have a bayonet cap with the cap used as an electrical contact or only as a mechanical support. Some miniature lamps may have a wedge base and wire contacts, and some automotive and special purpose lamps may include screw terminals for connection to wires. The arrangement of electrical contacts for any particular application will depend on the design parameters of that application.

As noted earlier, the mount 5003 may be a thermally conductive material to dissipate heat generated by the light emitting cells 5001, 5002. The mount 5003 may extend through a stack of spaced apart thermally conductive horizontal plates (not shown) located in the base 516, which function to dissipate the heat generated by the light emitting cells 5001, 5002 through one or more vents (not shown) in the base 516. As an alternative to the mount configuration described thus far, the mount 5003 may be configured as heat pipes that support the light emitting elements 5001, 5002.

A fan (not shown) may also be used to cool the light source 5000. The fan may be an electronic fan or some other suitable device that generates airflow to cool the light source 5000. An electronic fan is a device that generally exploits the concept of corona wind. Corona wind is a physical phenomenon that is produced by a strong electric field. These strong electric fields are often found at the tips of electrical conductors where electric charges, which reside entirely on the surface of the conductor, tend to accumulate. When the electric field reaches a certain strength, known as the corona discharge inception voltage gradient, the surrounding air is ionized with the same polarity as the tip of the conductor. The tip then repels the ionized air molecules surrounding it, thereby creating airflow. A non-limiting example of an electronic fan that exploits corona wind to generate airflow is an RSD5 solid-state fan developed by Ventiva or Thorrn Micro Technologies, Inc. The fan may be mounted in close proximity to the light source 5000. Those skilled in the art will be readily able to determine the location of the fan best suited for any particular application based on the overall design parameters.

Power may be applied to the light source 5000 through the electrical contacts 530a and 530b. An AC-DC converter (not shown) may be used to generate a DC voltage from a lamp socket connected to a wall-plug in a household, office building, or other facility. The DC voltage generated by the AC-DC converter may be provided to a driver circuit (not shown) configured to drive the light source 5000. The AC-DC converter and the driver circuit may be located in the base 516, in the light source 5000, or anywhere else in the housing 512. In some applications, the AC-DC converter may not be needed. By way of example, the light source 500 may be designed for AC power. Alternatively, the power source may be DC, such as the case might be in automotive applications. The particular design of the power delivery circuit for any particular application is well within the capabilities of one skilled in the art.

As discussed in greater detail earlier, a white light source may be constructed from a substrate carrying multiple blue or UV LEDs and a phosphor material to produce a white light source. Alternatively, the phosphor material may be formed on the inner surface of transparent bulb portion 514 of the housing 512 to produce a white light source. In another configuration of a lamp, a white light source may be produced by embedding the phosphor material in the transparent bulb portion 514 of the housing 512. These concepts are more fully described in U.S. patent application Ser. No. 12/360,781, entitled “Phosphor Housing for Light Emitting Diode Lamp,” the contents of which is incorporated by reference as though fully set forth herein.

The various aspects of this disclosure are provided to enable one of ordinary skill in the art to practice the present invention. Various modifications to aspects presented throughout this disclosure will be readily apparent to those skilled in the art, and the concepts disclosed herein may be extended to other lamp configurations regardless of the shape or diameter of the glass enclosure and the base and the arrangement of electrical contacts on the lamp. By way of example, these concepts may be applied to bulb shapes commonly referred to in the art as A series, B series, C-7/F series, ER, G series, GT, K, P-25/PS-35 series, BR series, MR series, AR series, R series, RP-11/S series, PAR Series, Linear series, and T series; ED17, ET, ET-18, ET23.5, E-25, BT-28, BT-37, BT-56. These concepts may also be applied to base sizes commonly referred to in the art as miniature candela screw base E10 and E11, candela screw base E12, intermediate candela screw base E17, medium screw base E26, E26D, E27 and E27D, mogul screw base E39, mogul Pf P40s, medium skirt E26/50×39, candela DC bay, candela SC bay B15, BA15D, BA15S, D.C. Bayonet, 2-lug sleeve B22d, 3-lug sleeve B22-3, medium Pf P28s, mogul bi-post G38, base RSC, screw terminal, disc base, single contact, medium bi-post, mogul end prong, spade connector, mogul pre-focus and external mogul end prong; admedium skirted, medium skirted, position-oriented mogul, BY 22 D, Fc2, ceramic spade series (J, G, R), RRSC, RSC; single pin series, bi-pin series, G, GX, 2G series. Thus, the claims are not intended to be limited to the various aspects of this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

1. A light source, comprising:
a mount having first and second opposite surfaces;
a first light emitting element having one or more solid state light emitting cells arranged to emit light from the first surface of the mount; and
a second light emitting element having one or more solid state light emitting cells arranged to emit light from the second surface of the mount;
wherein the first and second light emitting elements are arranged such that the light emitted from the light source produces a substantially spherical emission pattern.

2. The light source of claim 1 wherein the one or more solid state light emitting cells for each of the first and second light emitting elements comprise a plurality of solid state light emitting cells arranged in a planar fashion.

3. The light source of claim 1 wherein each of the first and second light emitting elements comprises phosphor.

4. The light source of claim 1 wherein the first light emitting element comprises a first substrate attached to the first surface and the second light emitting element comprises a second substrate attached to the second surface.

5. The light source of claim 4 wherein the one or more solid state light emitting cells for the first light emitting element are supported by the first substrate and the one or more solid state light emitting cells for the second light emitting element are supported by the second substrate.

6. The light source of claim 1 wherein the one or more solid state light emitting for the first light emitting element are attached to the first surface of the mount and the one or more solid state light emitting for the second light emitting element are attached to the second surface.

7. The light source of claim 1 wherein the mount is thermally conductive.

8. A light source, comprising:
a mount;
a first light emitting element having one or more solid state light emitting cells; and
a second light emitting element having one or more solid state light emitting cells;
wherein the first and second light emitting elements arranged with the mount to emit light in opposite directions so that the light emitted from the light source has a substantially spherical emission pattern.

9. The light source of claim 8 wherein the one or more solid state light emitting cells for each of the first and second light emitting elements comprise a plurality of solid state light emitting cells arranged in a planar fashion.

10. The light source of claim 8 wherein each of the first and second light emitting elements comprises phosphor.

11. The light source of claim 8 wherein the first light emitting element comprises a first substrate attached to the first surface and the second light emitting element comprises a second substrate attached to the second surface.

12. The light source of claim 11 wherein the one or more solid state light emitting cells for the first light emitting element are supported by the first substrate and the one or more solid state light emitting cells for the second light emitting element are supported by the second substrate.

13. The light source of claim 8 wherein the one or more solid state light emitting for the first light emitting element are attached to the first surface of the mount and the one or more solid state light emitting for the second light emitting element are attached to the second surface.

14. The light source of claim 8 wherein the mount is thermally conductive.

15. A light source, comprising:
a mount;
a first light emitting element having one or more solid state light emitting cells; and
a second light emitting element having one or more solid state light emitting cells;
wherein the first and second light emitting elements are attached to opposite sides of the mount to produce a substantially spherical emission pattern from the light source.

16. The light source of claim 1 wherein the one or more solid state light emitting cells for each of the first and second light emitting elements comprise a plurality of solid state light emitting cells arranged in a planar fashion.

17. The light source of claim 15 wherein each of the first and second light emitting elements comprises phosphor.

18. The light source of claim 15 wherein the first light emitting element comprises a first substrate attached to the first surface and the second light emitting element comprises a second substrate attached to the second surface.

19. The light source of claim 18 wherein the one or more solid state light emitting cells for the first light emitting element are supported by the first substrate and the one or more solid state light emitting cells for the second light emitting element are supported by the second substrate.

20. The light source of claim 15 wherein the one or more solid state light emitting for the first light emitting element are attached to the first surface of the mount and the one or more solid state light emitting for the second light emitting element are attached to the second surface.

21. The light source of claim 15 wherein the mount is thermally conductive.

22. A lamp, comprising:
a housing having a base and a transparent bulb portion mounted to the base; and
a light source within the housing, the light source comprising:
a mount having first and second opposite surfaces;
a first light emitting element having one or more solid state light emitting cells arranged to emit light from the first surface of the mount; and
a second light emitting element having one or more solid state light emitting cells arranged to emit light from the second surface of the mount;
wherein the first and second light emitting elements are arranged such that the light emitted from the transparent bulb portion produces a substantially spherical emission pattern.

23. The lamp of claim 22 wherein the one or more solid state light emitting cells for each of the first and second light emitting elements comprise a plurality of solid state light emitting cells arranged in a planar fashion.

24. The lamp of claim 22 wherein each of the first and second light emitting elements comprises phosphor.

25. The lamp of claim 22 wherein the first light emitting element comprises a first substrate attached to the first surface and the second light emitting element comprises a second substrate attached to the second surface.

26. The lamp of claim 25 wherein the one or more solid state light emitting cells for the first light emitting element are supported by the first substrate and the one or more solid state light emitting cells for the second light emitting element are supported by the second substrate.

27. The lamp of claim 22 wherein the one or more solid state light emitting for the first light emitting element are attached to the first surface of the mount and the one or more solid state light emitting for the second light emitting element are attached to the second surface.

28. The lamp of claim 22 wherein the mount is thermally conductive.

29. The lamp of claim 22 further comprising a fan arranged within the housing to cool the solid state light emitting cells.

30. The lamp of claim 22 wherein the base is configured to electrically and mechanically mate with a lamp socket.

31. The lamp of claim 22 wherein the base comprises electrical contacts coupled to the solid state light emitting cells.

32. The lamp of claim 31 wherein the base comprises a cap configured to mechanically mate with the lamp socket, the cap comprising one of the electrical contacts.

33. The lamp of claim 32 wherein the base further comprises a tip having another one of the electrical contacts.

34. The lamp of claim 32 wherein the cap comprises a screw cap.

35. A lamp, comprising:
a housing having a base and a transparent bulb portion mounted to the base;
a light source within the housing, the light source comprising a mount and one or more light emitting elements arranged with the mount such that the light emitted from the transparent bulb portion produces a substantially spherical emission pattern, each of the one or more light emitting elements having one or more solid state light emitting cells; and
means for cooling the light source.

36. The lamp of claim 35 wherein the means for cooling the light source comprises a fan arranged within the housing to cool the one or more solid state light emitting cells.

37. The lamp of claim 36 wherein the fan comprises an electronic fan.

38. The lamp of claim 35 wherein the mount is thermally conductive.

39. The lamp of claim 38 wherein the means for cooling the light source comprises a plurality of spaced apart thermally conductive plates in the base, wherein the thermally conductive mount is arranged with the plates to dissipate heat generated by the one or more solid state light emitting cells.

40. The lamp of claim 38 wherein the means for cooling the light source comprises a plurality of spaced apart thermally conductive plates in the base, wherein the thermally conductive mount extends through the plates.

41. The lamp of claim 38 wherein the means for cooling the light source comprises one or more vents in the base, wherein the thermally conductive mount is arranged with the vents to dissipate heat generated by the one or more solid state light emitting cells.

42. The lamp of claim 38 wherein the thermally conductive mount comprises one or more heat pipes.

43. The lamp of claim 35 wherein the mount comprises first and second opposite surfaces, wherein the one or more light emitting elements comprise a first light emitting element arranged to emit light from the first surface of the mount and a second light emitting element arranged to emit light from the second surface of the mount.

44. The lamp of claim 35 wherein the one or more light emitting elements comprise first and second light emitting elements arranged with the mount to emit light in opposite directions.

45. The lamp of claim 35 wherein the one or more light emitting elements comprise first and second light emitting elements are attached to opposite sides of the mount.
